(19) United States
(12) Patent Application Publication
(10) Pub. No.: US 2006/0278942 A1
(43) Pub. Date: Dec. 14, 2006

(54) Antistiction MEMS substrate and method of manufacture

(75) Inventor: Paul J. Rubel, Santa Barbara, CA (US)

Correspondence Address: Jaquelin K. Spong, 2246 Mohegan Drive Apt. A1, Falls Church, VA, 22043, US

(73) Assignee: Innovative Micro Technology, Goleta, CA (US)

(21) Appl. No.: 11/151,415

(22) Filed: Jun. 14, 2005

(51) Int. Cl. H01L 29/84; H01L 21/00; C23C 16/00

(52) U.S. Cl. 257/415; 118/715; 438/50

(57) ABSTRACT

A composite wafer for fabricating MEMS devices is provided with a plurality of antistiction bumps, buried under a device layer of the composite wafer. The antistiction bumps are prepared lithographically, by patterning an antistiction material prior to the assembly of the composite wafer.

### CROSS REFERENCE TO RELATED APPLICATIONS

Not applicable.

### STATEMENT REGARDING FEDERALLY SPONSORED RESEARCH

Not applicable.

### STATEMENT REGARDING MICROFICHE APPENDIX

Not applicable.

### BACKGROUND

This invention relates to features incorporated into a substrate to reduce stiction between a MEMS device built upon the substrate and the substrate.

Moveable devices such as sensors and actuators are now often fabricated on a substrate surface using lithographic processing previously used to manufacture semiconductor electronic devices. Such moveable devices and their associated processing techniques are known as microelectromechanical systems, or MEMS.

MEMS are generally processed using one of two different methods. One method, referred to as surface micro machining, entails the device being fabricated by the building or stacking of layers of materials. Some of these materials may be structural, while other materials may be sacrificial in nature, and are used to create spacing between device features. These sacrificial materials will be removed prior to the complete fabrication of the device. The second method, referred to as bulk micro machining, entails the bonding of substrates and sacrificial layers first. The devices are then formed in the bonded substrates by various etching techniques. The devices are freed by removing the sacrificial layers in between the substrates. Bulk micro machining generally uses silicon-on-insulator(SOI) technology. The technology consists of two or more silicon substrates bonded together with a silicon dioxide sacrificial layer in between them One of the silicon substrates is referred to as the “handle” wafer, and may be the base of the SOI wafer. The second substrate is referred to as the “device” layer. This layer is generally thinned down to a range of about 0.5 μm to about 100 μm The device itself will be fabricated in this substrate.

An exemplary SOI substrate is shown in FIG. 1. The fabrication process for the SOI wafer begins with a handle wafer 10, of typically about 675 μm in thickness. A relatively thin (about 1 μm thick) sacrificial oxide layer 20 is then grown on the surface of this handle wafer 10 using thermal oxidation techniques in which the substrates are exposed to high temperature, above 1000 degrees, oxygen environment. A device layer 30 of equal thickness to the base or handle wafer 10 is bonded to the oxide layer 20 using fusion bonding techniques. The fusion bonding may include chemically treating the silicon dioxide and silicon surfaces to make them oxygen depleted. The device layer 30 and the handle wafer 10 may then be aligned and pressed together in a wafer bonding system, to first weakly bond the two wafers. The bonded pair consisting of handle wafer 10 and device layer 30 may then be annealed in a high heat furnace, for example, to temperatures of 1000 degrees centigrade. The device layer 30 may then be ground or chemically etched to the desired thickness. At this point the SOI wafer is ready for use in the MEMS fabrication process.

Because of the small size of the MEMS structures, they may have relatively little structural rigidity, and may, during the course of fabrication or after completion, bend down and touch the handle wafer. Upon touching the substrate, the devices may become adhered to the substrate surface by stiction forces or meniscus forces. Such meniscus forces may occur, for example, upon etching a layer beneath the moveable member with a wet etching solution, and then drying the etching solution from the substrate. Because the small devices may have relatively low torque or low rigidity, they may be unable to free themselves after becoming adhered to the substrate surface, rendering the devices non-functional.

Because of this tendency for MEMS devices to become adhered to the substrate surface, a number of techniques have been proposed for reducing the stiction between the device and the substrate surface. For example, U.S. Pat. No. 5,314,572 to Core, et al., teaches the use of photoresist pedestals which are inserted into a sacrificial layer between a suspended MEMS device and the substrate surface. Photoresist spacers are inserted in the MEMS microstructure layer between non-contacting portions of the suspended MEMS microstructure so that the photoresist pedestals and spacers support the microstructure bridge during the wet etching and drying process used to remove the sacrificial layer.

In another example, U.S. Pat. No. 6,538,798 to Miller et al. teaches stiction plugs which are formed on an optical membrane structure which is separated from the support substrate by an electrostatic cavity. The plugs extend from a surface of the membrane, and may be hollow to allow subsequent release of the underlying sacrificial layer. The plugs reduce the stiction forces by reducing the contact area between the membrane and the support substrate.

Finally, it has been proposed to coat the surfaces of a composite substrate such as a silicon-on-insulator (SOI) wafer with a very thin (e.g., monolayer) coating of low stiction material based on chlorosilanes such as diallyldichloromethylsilane, before the fabrication of the MEMS device.

### SUMMARY

A number of disadvantages are associated with the techniques disclosed in the prior art. In particular, the techniques which add small features to the MEMS device are relatively complex to implement, adding numerous additional steps to the photolithographic processing of the device. This additional processing adds cost to the device.

The approach of adding a monolayer of material to the substrate surface also has disadvantages. In particular, the very thin films are not robust to high temperature processing steps that may be required in the subsequent formation of the MEMS device. At temperatures in excess of, for example, 300 degrees centigrade, the monolayer films may volatilize. Therefore, this technique is not compatible with high temperature fabrication processes and typical wafer bonding processes such as anodic bonding, in which a voltage is applied between the materials at a temperature of between 400 and 600 degrees centigrade. The inability to use wafer bonding may prevent the use of wafer level packaging and force the use of standard more expensive packaging techniques. In addition, the techniques may require very strict levels of cleanliness, as even low levels of contamination may adversely affect the coating uniformity, or may lead to delamination of the coating.

Systems and methods are described for fabrication of antistiction bumps within a composite substrate for forming a MEMS device. The bumps may be placed underneath an overhanging moveable portion of a MEMS device. In contrast to the prior art techniques, the bumps are formed on the substrate surface before fabrication of the moveable device. Therefore, the systems and methods are relatively straightforward to implement in the process flow, and only a single additional photolithographic masking step is required.

The systems and methods may include a composite wafer for fabricating a moveable device, comprising a layer of antistiction material formed over portions of a substrate, a sacrificial layer formed over the portions of the substrate not covered by the antistiction material, and a device layer coupled to the sacrificial layer.

The antistiction bumps are formed by the antistiction material which covers portions of the substrate. Because the antistiction material may not support the growth of an oxide layer, when the oxide layer is grown over the other portions of the substrate, indentations may remain in the oxide layer at the locations of the antistiction bumps. When the oxide layer is subsequently removed to release a moveable device formed in the device layer, the antistiction bumps may remain as prominances between the moveable device and the substrate. The antistiction bumps may reduce the stiction forces at the interface between the moveable device and the substrate, by providing a lower stiction material interface and a reduced area of contact. These antistiction bumps may be formed randomly over the substrate surface, or they may be formed in specific locations to reduce the stiction forces for specific devices.

These and other features and advantages are described in, or are apparent from, the following detailed description.

### BRIEF DESCRIPTION OF THE DRAWINGS

Various exemplary details are described with reference to the following figures, wherein:

FIG. 1 is a cross sectional view of an exemplary prior art silicon-on-insulator substrate;

FIG. 2 is a cross sectional view of an exemplary wafer after a first step of fabrication;

FIG. 3 is a cross sectional view of the exemplary wafer after a second step of fabrication;

FIG. 4 is a cross sectional view of the exemplary wafer after a third step of fabrication;

FIG. 5 is a plan view of the exemplary wafer showing the placement of the antistiction bumps;

FIG. 6 is a cross sectional view of the exemplary wafer after a fourth step of fabrication;

FIG. 7 is a cross sectional view of the exemplary wafer after a fifth step of fabrication;

FIG. 8 is a cross sectional view of the exemplary wafer after a sixth step of fabrication; a and

FIG. 9 is a cross sectional view of the exemplary wafer after a seventh step of fabrication; and

FIG. 10 is a cross sectional view of the exemplary wafer after a final step of fabrication.

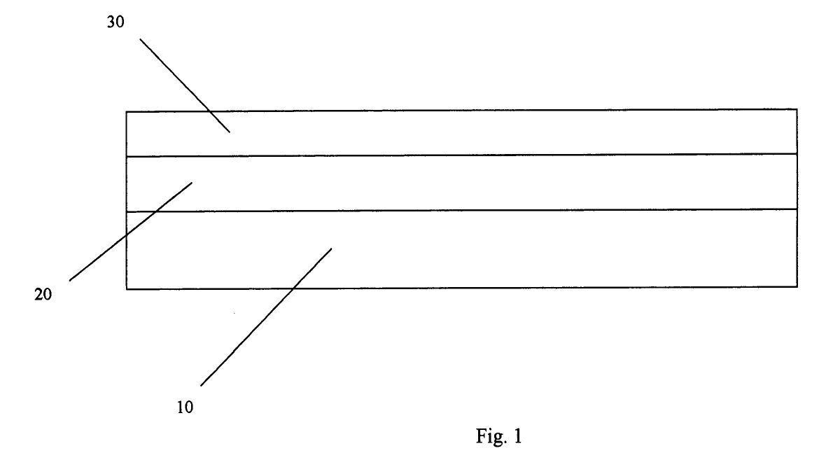

### DETAILED DESCRIPTION

The systems and methods described herein may be particularly applicable to silicon-on-insulator substrates, which are commonly used to fabricate MEMS devices. As described above, SOI wafers are often used in MEMS processsing, because the oxide layer 20 forms a convenient etch stop for etching the device features in the device layer 30. The movable features in the device layer 30 are then freed from the handle wafer 10 by etching away the oxide middle layer 20 underneath the moveable features.

The antistiction bumps may be fabricated from a layer of low stiction overcoat material patterned on the silicon handle wafer, before the handle wafer is oxidized to form the sacrificial layer of silicon dioxide. Thereafter, the device layer of the SOI substrate is deposited or bonded over the silicon dioxide sacrificial layer. Finally, the MEMS device is formed in the silicon device layer. The MEMS device may be located to be precisely over one or more of the antistiction bumps, or the antistiction bumps may be located randomly over the handle wafer surface.

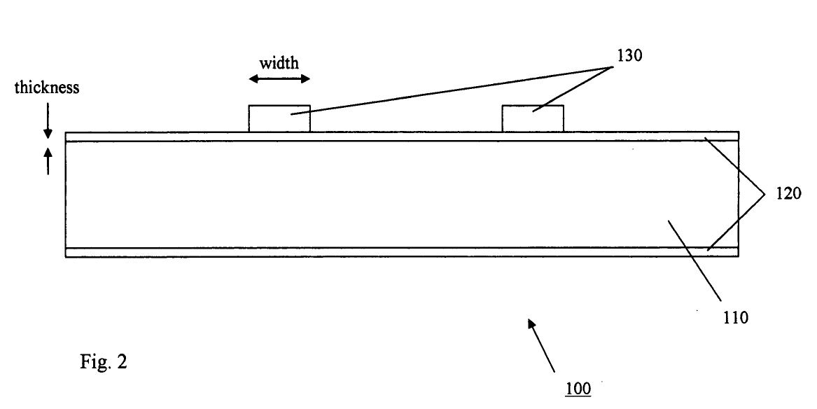

FIG. 2 is a cross sectional view of an exemplary wafer 100 after a first step in the fabrication of the MEMS antistiction bumps. A substrate 110 is first overcoated with a layer of durable, antistiction material, that is, material which has a relatively low coefficient of static friction with silicon. The antistiction material may have a lower coefficient of static friction than a layer of silicon would have with another layer of silicon. In one exemplary embodiment, the substrate 110 is a thick silicon handle wafer and the overcoat layer 120 is silicon nitride Si₃N₄. In another exemplary embodiment, the overcoat layer 120 may be polycrystalline silicon, or polysilicon. The thickness of the overcoat layer 120 may be, for example, between about 500 Angstroms and about 3000 Angstroms, and is preferably about 2000 Angstroms in thickness. The overcoat layer 120 may be deposited by, for example, low pressure chemical vapor deposition (LPCVD). The LPCVD process may be undertaken with a furnace temperature of between about 375 and about 700 degrees centigrade. A layer of photoresist 130 is then deposited on the overcoat layer 120, in order to pattern the antistiction bumps in the overcoat layer 120. The photoresist is patterned by exposure through a photolithographic mask, which illuminates certain areas of the photoresist. If a positive photoresist 130 is used, the exposed areas are then dissolved in an appropriate solvent and removed. If a negative photoresist is used, the unexposed areas are dissolved and removed. The width of a characteristic dimension of the photoresist structures 130, and therefore the width of the antistiction silicon nitride bumps 120, may be between about 15 μm and about 100 μm, and may preferably be about 20 μm. However, other widths may be chosen depending on the application. In fact, because these features are formed photolithographically, features with characteristic dimensions less than about 5 μm or greater than 100 μm may be formed.

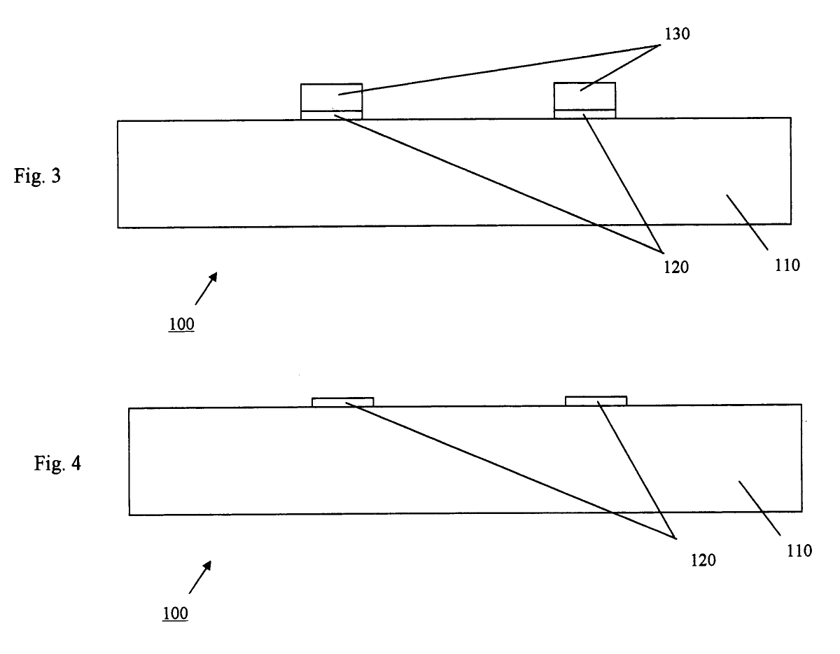

FIG. 3 is a cross sectional view of the exemplary wafer 100 after a second step of fabrication of the antistiction bumps. In FIG. 3, the overcoat layer 120 is removed everywhere that it is not covered by photoresist 130. The overcoat layer 120 may be removed by, for example, wet etching using phosphoric acid or dry etching using reactive ion etching with CF4 gas. The wet etching solution attacks the overcoat layer 120 everywhere that it is not protected by photoresist 130, removing it from the substrate or handle wafer 110. This results in the formation of anti-stiction bumps, or overcoated regions, also referred to with reference number 120.

FIG. 4 is a cross section of the exemplary wafer 100 after the remaining photoresist 130 is removed by dissolving in an appropriate solvent. This leaves only the antistiction bumps or overcoat regions 120 on the surface of the substrate 110. As set forth above, the antistiction bumps or overcoat regions 120 may have a characteristic dimension which may be, for example, about 15 μm. The shape of the antistiction bumps or overcoat regions 120 may be any shape which can be formed photolithographically, for example, circles, rectangles, stars, or complex shapes intended to follow the outline of the portion of the MEMS device which will be overhanging the antistiction bumps or overcoat regions 120. The means for forming the layer of antistiction material, that is, the overcoat layer 120, over portions of the substrate 110 may be the LPCVD deposition chamber, and the photolithographic equipment used to pattern the photoresist layer 130.

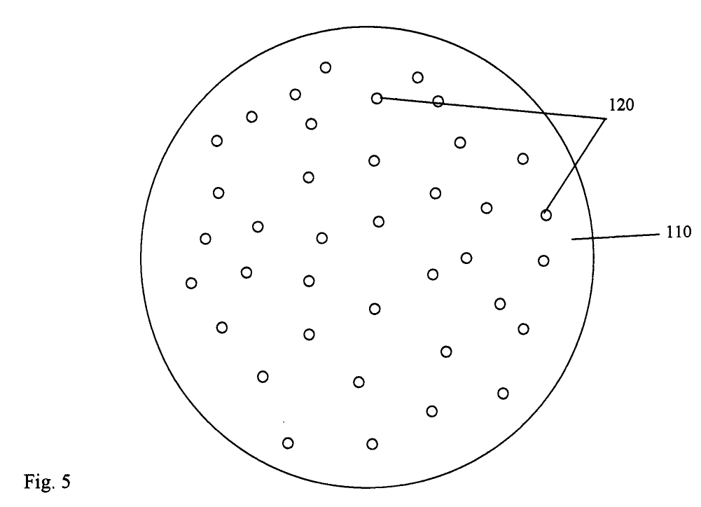

FIG. 5 is a plan view showing one exemplary embodiment of the antistiction bumps 120 located randomly over the surface of the substrate 110. In another exemplary embodiment, the antistiction bumps 120 are located only in specific areas which will correspond to the location of a MEMS device that will be fabricated in the silicon device layer yet to be bonded to substrate 110.

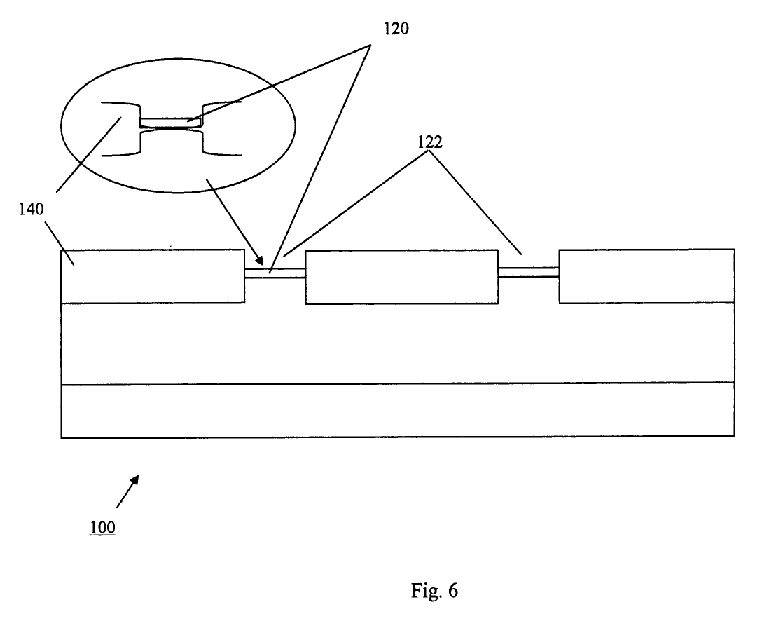

FIG. 6 is a cross sectional view of the exemplary wafer 100 after a fourth step of fabrication. In the fourth step, a sacrificial layer 140 is grown or deposited over the substrate 110. In one embodiment, the sacrificial layer 140 is silicon dioxide, which may be thermally grown or sputter-deposited over the silicon substrate 110 to a thickness of between about 1 μm and about 2 μm The sacrificial layer 140 may have the feature that it grows only on the substrate surface, and not on the surface of the overcoat layer or antistiction bumps 120. The sacrificial layer 140 may be a thermal oxide layer, formed for example, by local oxidation of silicon (“LOCOS”) at 1000 degrees centigrade in an H₂O or O₂ environment. The means for forming a sacrificial layer 140 may therefore be a heated chamber in which the thermal oxide is formed.

The growth of the silicon dioxide layer 140 on an overcoated silicon substrate 110 may result in the formation of a “bird's beak” profile well known in the art of semiconductor processing, wherein the oxide 140 grows partially beneath the overcoat layer 120, but not over top of the overcoat layer 120. The bird's beak profile is shown in greater detail in the insert of FIG. 6, although for simplicity of depiction, the profile of the oxide layer 140 is shown elsewhere as a simple perpendicular wall in the silicon substrate. The partial growth of the sacrificial layer 140 under the overcoat layer 120 may serve as a wedge under the overcoat layer 120, raising the overcoat layer 120 slightly at the edges. This behavior may actually be favorable from a stiction point of view, as the raised edges may support the overhanging MEMS surface rather than the whole top surface of the overcoat layer 120. Because there is less surface area in contact, the raised edge contact has further reduced stiction compared to the full bump 120 contact.

Because the sacrificial layer 140 does not grow on top of the overcoat regions 120, the presence of the overcoat regions 120 causes depressions 122 in the sacrificial layer 140. The overcoat regions 120, which are silicon nitride in this embodiment, in the depressions 122 remain bare. The depressions 122 in the sacrificial layer 140 will reduce the stiction forces between the bumps and the subsequently fabricated MEMS device, as will be discussed further below.

It should be understood that if the sacrificial layer is deposited rather than grown, it may later be removed by etching the deposited sacrificial layer 140 from the region of the antistiction bumps or overcoated regions 120. This method may also be effective, although somewhat more complex than using a thermally grown sacrificial layer 140, as described above.

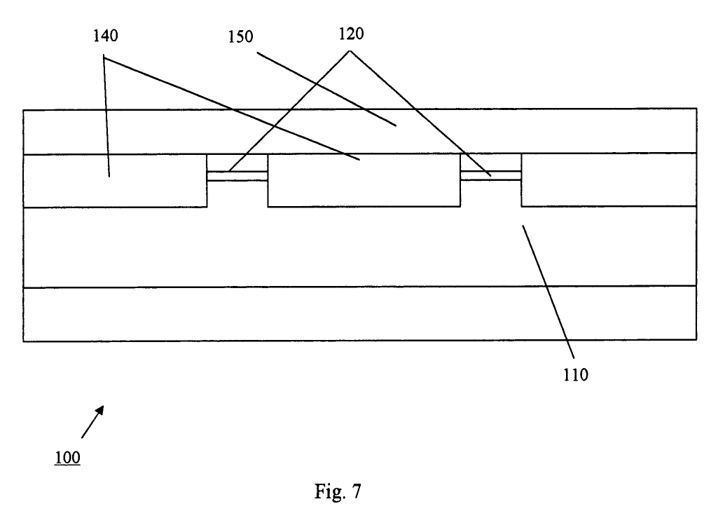

FIG. 7 is a cross sectional view of an exemplary wafer 100 after a fifth step of fabrication. In the fifth step of fabrication, a “device” layer of material 150 may be deposited, bonded or otherwise secured to the top of the sacrificial layer 140. This layer of material 150 may form the MEMS device after it has been patterned. In one exemplary embodiment, the layer of material may be a thinner silicon device layer 150, between about 1 μm and about 100 μm thick, which may be fusion bonded to the sacrificial layer 140. The silicon device layer 150 may initially be even thicker, and then have the excess material removed by, for example, grinding to the desired thickness. The means for coupling the device layer 150 to the sacrificial layer 140 may therefore be fusion bonding, which entails chemically treating the silicon dioxide and silicon surfaces to make them oxygen depleted The device layer 150 and the handle wafer 110 may then be aligned and pressed together in a wafer bonding system The wafers may bond weakly at this point. The bonded pair, consisting of handle wafer 110 and device layer 150, may then be annealed in a high heat furnace, for example, at temperatures of 1000 degrees centigrade.

With the addition of the device layer 150, the composite wafer structure may now have the construction of a silicon-on-insulator (SOI) wafer 100, well known in the MEMS art, except that the SOI wafer 100 has depressions 122 buried beneath the device layer 150. The SOI wafer 100 may now be patterned to form the MEMS structure. The specific details of the MEMS structure are not necessary to the understanding of the systems and methods described here. The MEMS structure may be, for example, an actuator, motor, switch, gyro or sensor, such as an accelerometer, whose suspended beam responds to the application of an acceleration in a direction perpendicular to the plane of the substrate.

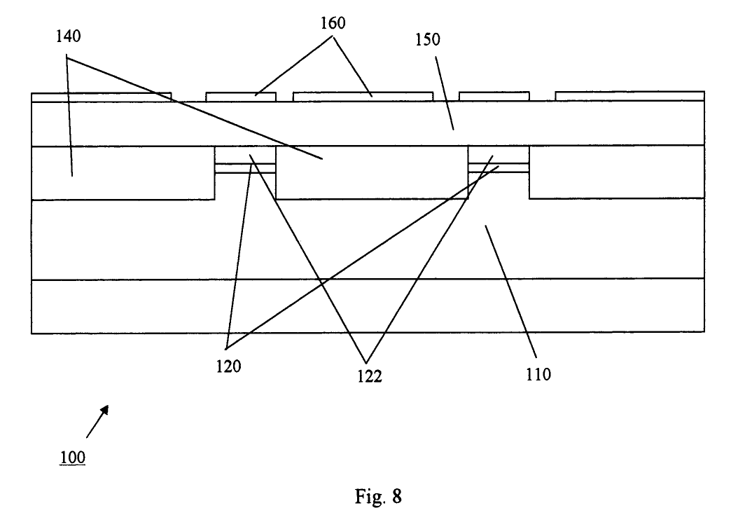

FIG. 8 is a cross sectional view of the exemplary SOI wafer 100 after a sixth step of fabrication In the sixth step, photoresist 160 may again be applied and patterned on the surface of the device layer 150. As before, the photoresist 160 may be either positive or negative photoresist, and the portion of the photoresist 160 is removed where the areas are to be etched to form the MEMS device. The pattern of the photoresist 160 may therefore correspond to the features desired in the MEMS device. Backside targets may be referenced to assure alignment of the proper features of the MEMS device with the depressions 122 in the sacrificial layer 140.

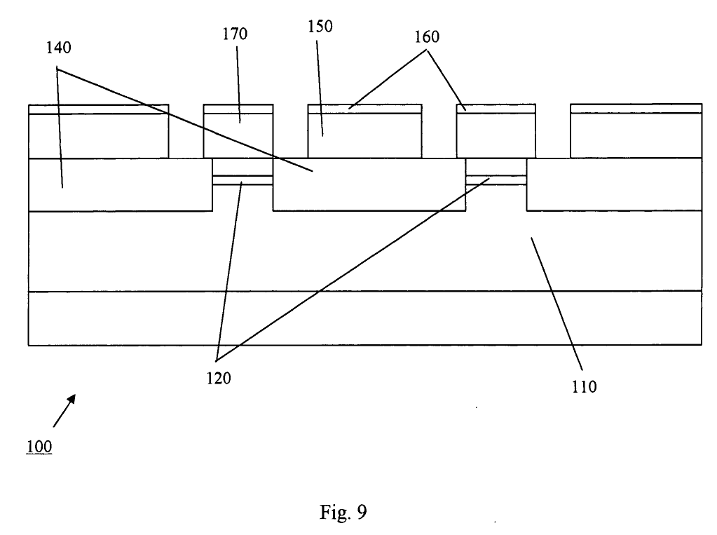

FIG. 9 is a cross sectional view of the exemplary SO wafer 100 after a seventh step of fabrication of the MEMS device. In FIG. 8, the moveable MEMS features 170 have been formed in the device layer 150, after a process which removes the device layer material 150 where it is not covered by photoresist. In one exemplary embodiment, the device layer 150 may be etched by Deep Reactive Ion Etching (DRIE) to form the features 170 of the MEMS device. Deep Reactive Ion Etching is a silicon etching process that achieves high aspect ratio features by combining alternating cycles of ion assisted chemical etching(SF6) with polymer deposition(C4F8). The etch rate of the polymer on the sides of a trench is much lower than that of the bottom. The ion assisted etching therefore etches the bottom of a trench, but etches a minima amount of material from the sides of the trench. This allows for the creation of high aspect ratio silicon trenches or structures. The mask providing the pattern may be oriented such that the moveable features 170 that require antistiction bumps are aligned with the depressions 122 in the buried sacrificial layer 140. The depressions 122 may not be located in etching sites 172 where the DRIE etching occurs. In other exemplary embodiments, the depressions 122 may be located under both the patterned features 170 and the etch sites 172. The remaining portions of the device layer 150 form the moveable features 170 of the MEMS device. These portions may be located over the depressions 122 caused by the buried overcoat regions 120 in the sacrificial oxide layer 140.

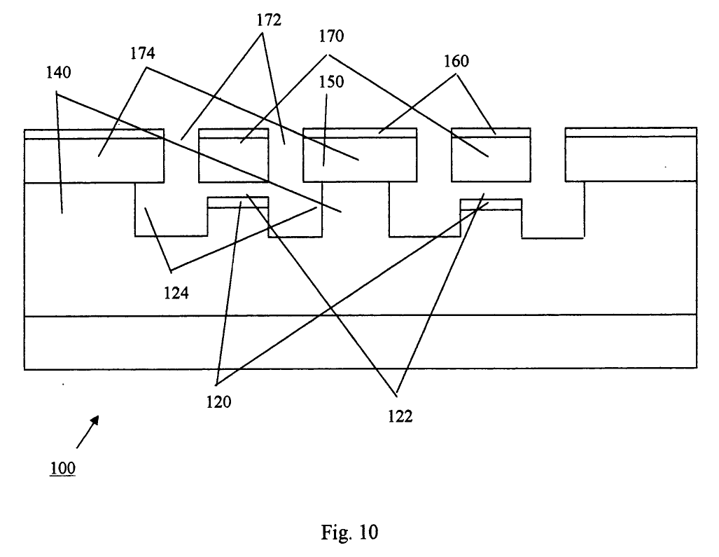

FIG. 10 is a cross sectional view of the exemplary SOI wafer 100 after a final step of fabrication of the MEMS device. This step includes the removal of the sacrificial layer 140 in the areas 122 under the moveable features 170 of the MEMS device. The sacrificial layer 140 may be removed by wet etching the wafer 100 in a solution of hydrofluoric acid (HF), for example. The depressions 122 may be located in close enough proximity to the DRIE etching sites 172 to allow for the wet buried sacrificial layer etching/release process to expose the depressions 122. By removing the sacrificial layer 140 near the depressions 122, the moveable features 170 of the MEMS device are freed from the substrate 110, and are therefore able to move as intended.

The wet etch solution is designed to also etch the overcoat layer 120 at a low rate. During the oxidation process, sacrificial layer 140 will grow underneath the overcoat layer 120, as shown in the insert of FIG. 6. When the sacrificial layer 140 is etched away, there will be a flap left of the overcoat layer 120. Since both sides of this flap on the overcoat layer 120 are exposed to the etchant, the sacrificial layer 140 underneath the overcoat layer 120 should etch at twice the rate as the overcoat layer 120. As a result, the overhanging flap of the overcoat layer 120 may be etched away, while still leaving a portion of the overcoat layer 120 on the top surface of the bump.

The sacrificial layer 140 may also be partially removed in other regions, such as regions 124 under the stationary portions 174 of the MEMS device which are not intended to be moveable, because the etch may be isotropic. However, because the regions 124 may be designed to be larger than the regions 122, such that the sacrificial layer 140 is completely removed in regions 122 while at least a portion of the sacrificial layer 140 remains to adhere the stationary portions 174 of the MEMS device to the substrate 110.

The overcoated bumps 120 on the handle wafer 110 may lower the stiction between the handle wafer 110 and the MEMS device 170 because: 1) their surface area of the contact interface is reduced; and 2) the contact interface will be silicon on the overcoat material 120, in this embodiment, silicon nitride, rather than silicon on silicon.

It may be important that the size of the antistiction regions 120 remain relatively small. If the depressed areas 122 become too large, their presence may interfere with the heat conduction capability of the device by reducing the silicon to silicon dioxide interface area

The spacing between the antistiction regions 120 is also important to control, to prevent the moveable features 170 from being pulled down when the sacrificial layer 140 is released. Taking into account the height of the bumps and the stiffness of the moveable features 170 to be released, the bump spacing can be calculated such that the structure in between the bumps is stiff enough to withstand the meniscus forces that occur during the drying process.

As described above with respect to FIGS. 2-10, the process described here may add only a single mask step to form the overcoat bump features. Thereafter, processing may be identical to that used to produce an ordinary SOI wafer, or to fabricate an ordinary MEMS structure on the SOI wafer. This allows the described system to be integrated easily into existing processes for manufacturing MEMS devices. It also indicates that the above process is relatively inexpensive to implement on existing high volume manufacturing lines.

The antistiction bumps may provide an additional benefit for some device applications. For example, the antistiction bumps can be used to limit the travel of a device structure in the direction toward the substrate 110. The thickness of the antistiction material 120 and the sacrificial layer 140 can be adjusted to control the distance between the device layer 150 and the top of the antistiction bump 120. This control maybe required to prevent damage to fragile devices, limit the motion of the device when subjected to forces or accelerations into the plane of the wafer. It may also be used as a method of defining the distance between the device layer 150 and the substrate 110. This could be beneficial in limiting or controlling interactions between the device layer 150 and the substrate 110. For example, the antistiction bump may hold the moveable features of the device layer 150 at a specified height above the substrate 110 defining the capacitance between the substrate 110 and the device layer 150.

While various details have been described in conjunction with the exemplary implementations outlined above, various alternatives, modifications, variations, improvements, and/or substantial equivalents, whether known or that are or may be presently unforeseen, may become apparent upon reviewing the foregoing disclosure. For example, while the invention has been described with respect to a buried silicon nitride layer, it should be understood that any of a number of alternative antistiction materials may be used for the purpose of providing the antistiction bumps on the substrate. Accordingly, the exemplary implementations set forth above, are intended to be illustrative, not limiting.

What is claimed is:

1. A composite wafer for fabricating a moveable device, comprising:
a layer of antistiction material formed over at least a portion of a substrate;
a sacrificial layer formed over the portions of the substrate not covered by the antistiction material; and
a device layer coupled to the sacrificial layer.

2. The wafer of claim 1, wherein the layer of antistiction material is patterned into regions of less than about 100 μm in at least one dimension.

3. The wafer of claim 2, wherein the regions occur randomly over the substrate.

4. The wafer of claim 1, wherein the antistiction material is silicon nitride, and the device layer is silicon.

5. The wafer of claim 1, wherein the sacrificial layer is silicon dioxide, and the substrate is silicon.

6. The wafer of claim 5, wherein the silicon dioxide is a thermally grown layer, with a thickness of between about 1 μm to about 2 μm.

7. The wafer of claim 1, wherein a moveable feature of the moveable device is formed in the device layer using photolithographic techniques.

8. The wafer of claim 1, wherein the layer of antistiction material is between about 500 Angstroms and about 3000 Angstroms thick and the sacrificial layer is about 1 μm thick.

9. The wafer of claim 1, wherein the moveable device is at least one of a sensor, motor, switch, accelerometer, gyro, and actuator.

10. A method of manufacturing a wafer for fabricating a moveable device, comprising:
forming a layer of antistiction material over at least a portion of a substrate;
forming a sacrificial layer over the portions of the substrate not covered by the antistiction material; and
coupling a device layer to the sacrificial layer.

11. The method of claim 10, further comprising:
forming the moveable device in the device layer using photolithographic techniques.

12. The method of claim 10, wherein the substrate is silicon and forming the sacrificial layer over the portions of the substrate not covered by the antistiction material comprises thermally growing a layer of silicon dioxide on the silicon substrate to a thickness of between about 1 μm to about 2 μm.

13. The method of claim 10, wherein forming the layer of antistiction material over at least a portion of the substrate comprises at least one of forming the layer of antistiction material over a portion located to contact a surface of the moveable device, and forming the layer of antistiction material over randomly located portions of the substrate.

14. The method of claim 11, further comprising removing at least a portion of the sacrificial layer which is under a moveable feature of the moveable device.

15. The method of claim 10, wherein forming the layer of antistiction material over at least a portion of the substrate comprises depositing a layer of silicon nitride using chemical vapor deposition to a thickness of between about 500 and about 3000 Angstroms, and patterning the silicon nitride layer to form a plurality of regions which are between about 15 μm and about 100 μm in at least one dimension.

16. The method of claim 15, wherein forming the layer of antistiction material over at least a portion of the substrate comprises depositing a layer of silicon nitride to a thickness of about 2000 Angstroms, and patterning the silicon nitride layer to form a plurality of regions about 20 μm in at least one dimension.

17. The method of claim 10, wherein forming the moveable device in the device layer comprises etching a feature of the moveable device using deep reactive ion etching.

18. The method of claim 10, wherein forming the layer of antistiction material over at least a portion of the substrate comprises depositing a layer of polycrystalline silicon to a thickness of about 2000 Angstroms.

19. The method of claim 10, wherein the substrate and the device layer are both silicon.

20. An apparatus for manufacturing a wafer for fabricating a moveable device, comprising:
means for forming a layer of antistiction material over at least a portion of a substrate;
means for forming a sacrificial layer over the portions of the substrate not covered by the antistiction material; and
means for coupling a device layer to the sacrificial layer.
